(19) United States
(12) Patent Application Publication
(10) Pub. No.: US 2013/0105956 A1
(43) Pub. Date: May 2, 2013

(54) POWER MODULE PACKAGE AND METHOD FOR MANUFACTURING THE SAME

(71) Applicant: Samsung Electro-Mechanics Co., Ltd., Gyunggi-do (KR)

(72) Inventors: Eun Jung Jo, Gyunggi-do (KR); Jae Hyun Lim, Gyunggi-do (KR); Tae Hyun Kim, Gyunggi-do (KR); Young Ho Sohn, Gyunggi-do (KR); Kwang Soo Kim, Gyunggi-do (KR); Young Hoon Kwak, Gyunggi-do (KR); Sun Woo Yun, Gyunggi-do (KR); Young Ki Lee, Gyunggi-do (KR); Kyu Hwan Oh, Gyunggi-do (KR); Jin Suk Son, Gyunggi-do (KR)

(73) Assignee: SAMSUNG ELECTRO-MECHANICS CO., LTD., Gyunggi-do (KR)

(21) Appl. No.: 13/659,497

(22) Filed: Oct. 24, 2012

(30) Foreign Application Priority Data
Oct. 31, 2011 (KR) 10-2011-0112335
Nov. 18, 2011 (KR) 10-2011-0121063

(51) Int. Cl. H01L 23/495; H01L 21/58

(52) U.S. Cl. 257/676; 438/123; 257/E23.042; 257/E21.505

(57) ABSTRACT

Disclosed herein is a power module package, including: a first lead frame; and a second lead frame. The first lead frame and the second lead frame may be spaced apart from each other, and the first lead frame and the second lead frame may have different thicknesses. In addition, the power module package further includes: a first semiconductor chip bonded to a first surface of one side of the first lead frame; and a second semiconductor chip bonded to a first surface of one side of the second lead frame.

### CROSS REFERENCE TO RELATED APPLICATION

This application claims the benefit of Korean Patent Application No. 10-2011-0121063, filed on Nov. 18, 2011, entitled “Power Module Package and Method of Manufacturing the Same”, Korean Patent Application No. 10-2011-0112335, filed on Oct. 31, 2011, entitled “Power Module Package” both of which are incorporated by reference herein in their entireties

### BACKGROUND OF THE INVENTION

1. Technical Field

The present invention relates to a power module package and a method for manufacturing the same.

2. Description of the Related Art

As an amount of used energy increases worldwide, a power conversion apparatus such as an inverter for home and industry has been increasingly employed for an efficient use of energy and protection of an environment.

An intelligent power module (IPM) spotlighting along with an increase in the employment of the inverter is a core parts performing functions of rectifying a DC and converting an AC and may be applied to home appliances such as a refrigerator, a washing machine, an air conditioner, etc., industrial appliances such as an industrial motor, and next generation appliances such as HEV, EV, etc.

In general, if heat is greatly generated during a power conversion process, and the generated heat is not efficiently removed, a module and a whole system may deteriorate in terms of performance and be damaged. Furthermore, since multi-function and small-size parts are essential to the IPM according to a recent tendency, an efficient dissipation of heat due to the multi-function and small-size parts is also an important factor as well as a structure enhancement for multi-function and small-size.

Meanwhile, a structure of a conventional power module package is disclosed in Korean Patent No. 0370231.

A conventional IPM has been implemented by placing a power device and a control device controlling the power device on one lead frame.

In the conventional structure, the power device and the control device are disposed on the lead frame having the same thickness. In this regard, a thick lead frame having a thickness greater than a predetermined level must be used to effectively dissipate heat generated from the power device having a high heating value.

However, the control device having a low heating value is also mounted on a thick lead frame that is not necessary for the control device, which is disadvantageously not efficient.

In addition, as described above, since the control device is mounted on the thick lead frame, a fine circuit is not easily formed.

In addition, according to one of the conventional manners, a direct bonded copper (DBC) substrate in which copper boards are sintered and bonded to both sides of a ceramic by heat and pressure is used.

However, the above-described DBC substrate has advantages of having excellent heat radiation property and heat conductivity property, but disadvantages of being expensive due to process characteristics therefor and being difficult to manufacture in a large size due to characteristics of thin ceramic.

Further, since the above-described DBC substrate has a structure where the copper boards are bonded to both surfaces of the ceramic, the copper boards may be delaminated from the ceramic.

### SUMMARY OF THE INVENTION

The present invention has been made in an effort to provide a power module package using lead frames having various thicknesses depending on capacities and a method for manufacturing the same.

Further, the present invention has been made in an effort to provide a power module package in which a power unit generating a great amount of heat and a control unit vulnerable to heat are thermally separated from each other, to allow heat generated from a power device to have an minimum effect on a control device and a method for manufacturing the same.

Further, the present invention has been made in an effort to provide a power module package capable of forming a fine circuit by applying a lead frame having a small thickness to a control unit and a method for manufacturing the same.

Further, the present invention has been made in an effort to provide a small-size power module package by implementing a control unit of a lead frame having a small thickness and a method for manufacturing the same.

Further, the present invention has been made in an effort to provide a power module package having improved heat radiation property.

Further, the present invention has been made in an effort to provide a power module package capable of reducing material costs and process costs.

Further, the present invention has been made in an effort to provide a power module package capable of preventing delamination between metal layers.

According to one preferred embodiment of the present invention, there is provided a power module package, including: a first lead frame; and a second lead frame, wherein the first lead frame and the second lead frame are spaced apart from each other, and the first lead frame and the second lead frame have different thicknesses.

The power module package may further include: at least one first semiconductor chip bonded onto a first surface of one side of the first lead frame; and at least one second semiconductor chip bonded onto a first surface of one side of the second lead frame.

In the case where the first semiconductor chip is a power device and the second semiconductor chip is a control device, the thickness of the second lead frame may be smaller than the thickness of the first lead frame.

The power module package may further include a molding material surrounding one side of the first lead frame, one side of the second lead frame, the first semiconductor chip, and the second semiconductor chip.

The power module package may further include a substrate contacting a second surface of one side of the first lead frame, the substrate including: a ceramic layer formed on a surface contacting the second surface of one side of the first lead frame; and a circuit pattern formed on the ceramic layer.

The power module package may further include a substrate contacting both a second surface of one side of the first lead frame and a second surface of one side of the second lead frame, the substrate including: a ceramic layer formed on a surface contacting both the second surface of one side of the first lead frame and the second surface of one side of the second lead frame; and at least one circuit pattern formed on the ceramic layer.

The power module package may further include: at least one first semiconductor chip bonded onto a first surface of one side of the first lead frame; and at leas one second semiconductor chip bonded onto a first surface of one side of the second lead frame.

The power module package may further include: at least one first semiconductor chip bonded onto a first surface of one side of the first lead frame; and at least one second semiconductor chip bonded onto the circuit pattern.

The power module package may further include at least one first semiconductor chip and at least one second semiconductor chip boned onto the at least one circuit pattern, wherein a circuit pattern to which the first semiconductor chip is bonded is spaced apart from a circuit pattern to which the second semiconductor chip is bonded.

According to another preferred embodiment of the present invention, there is provided a method for manufacturing a power module package, the method including: preparing a first lead frame including a first locking unit and a first module unit separately connected to the first locking unit and a second lead frame including a second locking unit and a second module unit separately connected to the second locking unit; and coupling the first lead frame and the second lead frame with each other by using the first locking unit and the second locking unit, wherein the first lead frame and the second lead frame have different thicknesses.

The first locking unit and the second locking unit may have holes corresponding to each other, respectively, and the coupling of the first lead frame and the second lead frame may be performed by fitting a hole of the first locking unit and a hole of the second locking unit to a protrusion unit formed on a separate lead frame coupling member.

The method may further include, after the coupling of the first lead frame and the second lead frame, bonding a first semiconductor chip and a second semiconductor chip onto a first surface of one side of the first module unit of the first lead frame and a first surface of one side of the second module unit of the second lead frame, respectively.

In the case where the first semiconductor chip is a power device and the second semiconductor chip is a control device, the thickness of the second lead frame may be smaller than the thickness of the first lead frame.

The method may further include, after the coupling of the first semiconductor chip and the second semiconductor chip, forming a molding material surrounding one side of the first module unit, one side of the second module unit, the first semiconductor chip, and the second semiconductor chip.

The method may further include: after the forming of the molding material, separating the first module unit and the second module unit, to which the first semiconductor chip and the second semiconductor chip are respectively bonded, from the first locking unit and the second locking unit, respectively, by performing a trimming process; and molding the other side of the first module unit and the other side of the second module unit, which protrude externally from the molding material by performing a foaming process.

The method may further include, before the bonding of the first semiconductor chip and the second semiconductor chip, forming a substrate contacting a second surface of one side of the first module unit of the first lead frame, the substrate including: a ceramic layer formed on a surface contacting the second surface of one side of the first lead frame; and a circuit pattern formed on the ceramic layer.

The method may further include, after the coupling of the first lead frame and the second lead frame, forming a substrate contacting both a second surface of one side of the first module unit of the first lead frame and a second surface of one side of the second module unit of the second lead frame, the substrate including: a ceramic layer formed on a surface contacting the second surface of one side of the first module unit of the first lead frame and a second surface of one side of the second module unit of the second lead frame; and at least one circuit pattern formed on the ceramic layer.

The method may further include, after the bonding of the substrate, bonding the first semiconductor chip and the second semiconductor chip onto the first surface of one side of the first module unit of the first lead frame and the first surface of one side of the second module unit of the second lead frame, respectively.

The method may further include, after the bonding of the substrate, bonding the first semiconductor chip and the second semiconductor chip onto the first surface of one side of the first module unit of the first lead frame and the circuit pattern, respectively.

The method may further include, after the bonding of the substrate, bonding the first semiconductor chip and the second semiconductor chip onto the at least one circuit pattern, wherein a circuit pattern to which the first semiconductor chip is bonded is spaced apart from a circuit pattern to which the second semiconductor chip is bonded.

### BRIEF DESCRIPTION OF THE DRAWINGS

FIG. 1 is a cross-sectional view of a structure of a power module package according to a first embodiment of the present invention;

FIG. 2 is a cross-sectional view of a structure of a power module package according to a second embodiment of the present invention;

FIG. 3 is a cross-sectional view of a structure of a power module package according to a third embodiment of the present invention;

FIG. 4 is a cross-sectional view of a structure of a power module package according to a fourth embodiment of the present invention;

FIG. 5 is a cross-sectional view of a structure of a power module package according to a fifth embodiment of the present invention;

FIGS. 6 through 11 are process views sequentially explaining a method for manufacturing the power module package according to the first embodiment of the present invention;

FIG. 12 is a plan view explaining an operation of bonding a substrate onto lead frames in a method for manufacturing the power module package according to the second embodiment of the present invention; and

FIGS. 13 and 14 are cross-sectional views explaining an operation of coupling a first lead frame and a second lead frame in a method for manufacturing the power module package according to each of the embodiments of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Preferred embodiments of the present invention will now be described in detail with reference to the accompanying drawings.

### Power Module Package

### First Embodiment

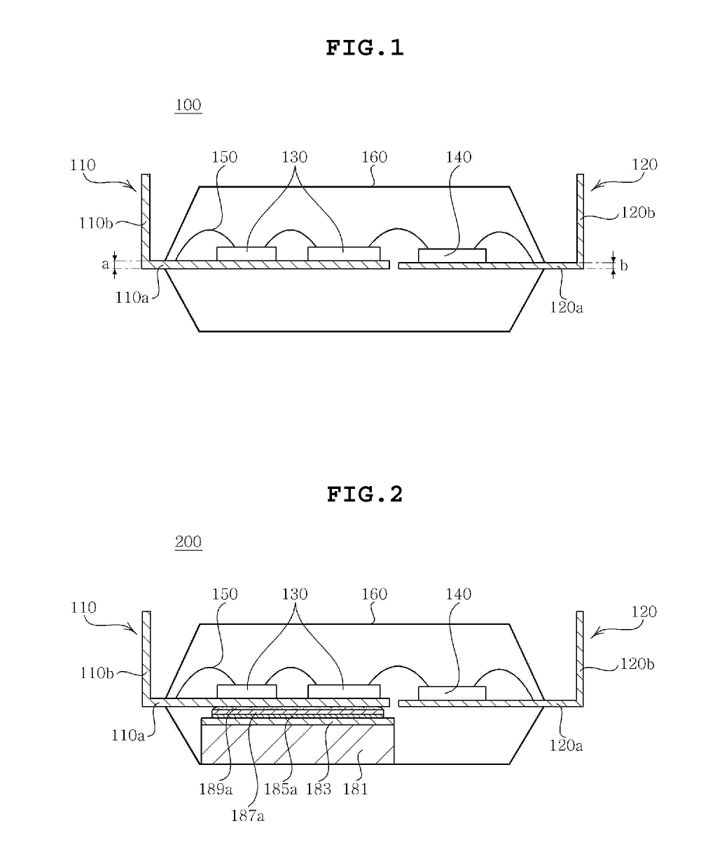

FIG. 1 is a cross-sectional view of a structure of a power module package according to a first embodiment of the present invention.

A ‘first surface’ and a ‘second surface’ described throughout the specification may mean an ‘upper surface’ and a ‘lower surface’ in a thickness direction of the first lead frame and the second lead frame each, respectively, but the present invention is not particularly limited thereto.

Referring to FIG. 1, a power module package 100 of the present embodiment includes a first lead frame 110 having a first surface of one side 110a, to which first semiconductor chips 130 are bonded, and a second lead frame 120 spaced apart from the first lead frame 110 and having a first surface of one side 120a, on which a second semiconductor chip 140 is mounted.

In the present embodiment, the first lead frame 110 and the second lead frame 120 may have different thicknesses.

For example, if the first semiconductor chips 130 are power devices and the second semiconductor chip 140 is a control device, as shown in FIG. 1, a thickness a of the first lead frame 110 may be greater than a thickness b of the second lead frame 120. However, this is merely one embodiment, and the present invention is not particularly limited thereto.

That is, a power device that radiates a great amount of heat is bonded onto a lead frame having a great thickness and high heat conductivity, whereas a control device that radiates a small amount of heat does not need to have high heat conductivity, and thus is bonded onto a lead frame having a small thickness.

As described above, lead frames having different thicknesses are applied depending on the amount of heat radiation, thereby achieving efficient heat radiation property and simultaneously reducing manufacturing cost by reducing the unnecessary use of lead frames.

Further, thicknesses of lead frames bonded onto a control device are reduced, thereby facilitating formation of a fine circuit of a control unit for high integration.

In this regard, although a pair of lead frames including the first lead frame 110 and the second lead frame 120 is shown in FIG. 1, this is merely shown through a cross-sectional view, and it would be obvious that several pairs of lead frames may be formed.

Although not shown in FIG. 1, the first semiconductor chips 130 and the second semiconductor chip 140 may be bonded onto the first lead frame 110 and the second lead frame 120, respectively, by using a bonding adhesive (not shown). The bonding adhesive (not shown) may be conductive or non-conductive.

For example, the bonding adhesive (not shown) may be formed by plating, or may be a conductive paste or a conductive tape. Further, the bonding adhesive (not shown) may be a solder, metal epoxy, a metal paste, resin-based epoxy, or a bonding tape having excellent heat resistance.

For example, the bonding tape that may be used as the bonding adhesive (not shown) may be a high temperature tape such as a commercialized well-known glass tape, a silicon tape, a Teflon tape, a stainless foil tape, and a ceramic tape. The bonding adhesive (not shown) may be formed of a combination of the above materials, but the present invention is not particularly limited thereto.

Further, the first semiconductor chip 130 may use a silicon controlled rectifier (SCR), a power transistor, an insulated gate bipolar transistor (IGBT), a Morse transistor, a power rectifier, a power regulator, an inverter, a converter, or a high power semiconductor chip of a combination of theses or diode, but the present invention is not particularly limited thereto.

Further, the second semiconductor chip 140 may include a low-power semiconductor chip for controlling the high-power semiconductor chip, for example, a control device for controlling a power device, but the present invention is not particularly limited thereto.

In the present embodiment, the first semiconductor chips 130 and the second semiconductor chip 140 respectively bonded onto the first lead frame 110 and the second lead frame 120 may be electrically connected to the first lead frame 110 and the second lead frame 120, respectively, through wire bonding using a wire 150.

In this regard, a wire bonding process may be preformed through ball bonding, wedge bonding, and stitch bonding that are well-known in the art to which the present invention pertains, but the present invention is not particularly limited thereto.

Further, as shown in FIG. 1, the power module package 100 of the present embodiment may further include a molding material 160 formed to surround one side 110a of the first lead frame 110, one side 120a of the second lead frame 120, the first semiconductor chips 130, and the second semiconductor chip 140.

The molding material 160 protects the first semiconductor chips 130 and the second semiconductor chip 140, including wires 150, from an external environment. For example, an epoxy molding compound (EMC), etc., may be used for the molding material 160, but the present invention is not particularly limited thereto.

### Second Embodiment

FIG. 2 is a cross-sectional view of a structure of a power module package according to a second embodiment of the present invention.

Redundant descriptions between the first embodiment and the present embodiment will be omitted here, and the same reference numerals will denote the same elements therebetween.

Referring to FIG. 2, a power module package 200 of the present embodiment includes a first lead frame 110 having a first surface of one side 110a, to which first semiconductor chips 130 are bonded, a second lead frame 120 spaced apart from the first lead frame 110 and having a first surface of one side 120a, on which a second semiconductor chip 140 is mounted, and a substrate 181 contacting a second surface of one side 110a of the first lead frame 110.

In this regard, the second lead frame 120 may be stepped from the first lead frame 110. Also, although one side 120a of the second lead frame 120 may overlap one side 110a of the first lead frame 110, this is merely an example, and they may not overlap each other.

In addition, the pair of lead frames 110 and 120 is shown in FIG. 2, but this is merely shown through a cross-sectional view. Therefore, it would be obvious that several pairs of lead frames may be formed.

In this regard, the substrate 181 may be a metal substrate, but the present invention is not particularly limited thereto. Examples of the substrate 181 may include a printed circuit board (PCB), an insulated metal substrate (IMS), and a pre-molded substrate.

In the present embodiment, a ceramic layer 183 may be formed on one surface of the substrate 181, i.e. one of both surfaces of the substrate 181, which contacts the second surface of one side 110a of the first lead frame 110.

In this regard, the ceramic layer 183 may be formed by a spray process, a dipping process, a bar coating process, a spin coating process, etc., but the present invention is not particularly limited thereto.

In this case, since a desired thickness of ceramic may be easily formed according to the ceramic characteristics, the ceramic layer 183 of various thicknesses from 1 μm to 500 μm may be formed depending on uses thereof.

Further, roughness is formed on the surface of the substrate 181 before forming the ceramic layer 183, thereby enhancing a bonding force between the ceramic layer 183 and the substrate 181.

In this regard, the roughness may be formed by using sand blast, plasma processing, wet surface processing, brush buff, etc., but the present invention is not particularly limited thereto.

Also, in the present embodiment, a circuit pattern may be formed on the ceramic layer 183.

In this regard, as shown in FIG. 2, the circuit pattern may include an electroless plating layer 185a and an electroplating layer 187a, but the present invention is not particularly limited thereto.

Further, the circuit pattern may be a metal layer pattern including copper (Cu) or copper alloy. In this case, copper (Cu) may provide excellent electric conductivity, and a nickel (Ni) layer for preventing oxidation may be further formed on a copper circuit pattern.

Further, since the nickel (Ni) layer is not excellent in view of coating property with respect to copper (Cu) and thus may also be oxidized, a gold (Au) layer may be further formed on the nickel (Ni) layer.

However, the circuit pattern is not limited to the structure of the present embodiment, and may include metal or metal alloy having excellent electric conductivity. For example, the circuit pattern may include aluminum or aluminum alloy.

In the present embodiment, the second surface of one side 110a of the first lead frame 110 may be bonded onto the electroplating layer 187a in the circuit pattern, and the other side 110b thereof may be spaced apart from the substrate 181.

In this case, a bonding layer 189a may be further formed between the second surface of one side 110a of the first lead frame 110 and the electroplating layer 187a.

In this regard, the bonding layer 189a may be a solder, and one side 110a of the first lead frame 110 and the circuit pattern may be mechanically and electrically connected to each other by the bonding layer 189a.

As such, a ceramic layer having excellent heat radiation property is formed on one surface of the metal substrate, a circuit pattern with a minimum thickness is formed on the ceramic layer, and a lead frame is bonded onto the circuit pattern, and thus the lead frame functions as a heat radiation substrate, thereby reducing manufacturing cost of the heat radiation substrate and simultaneously improving heat radiation property.

### Third Embodiment

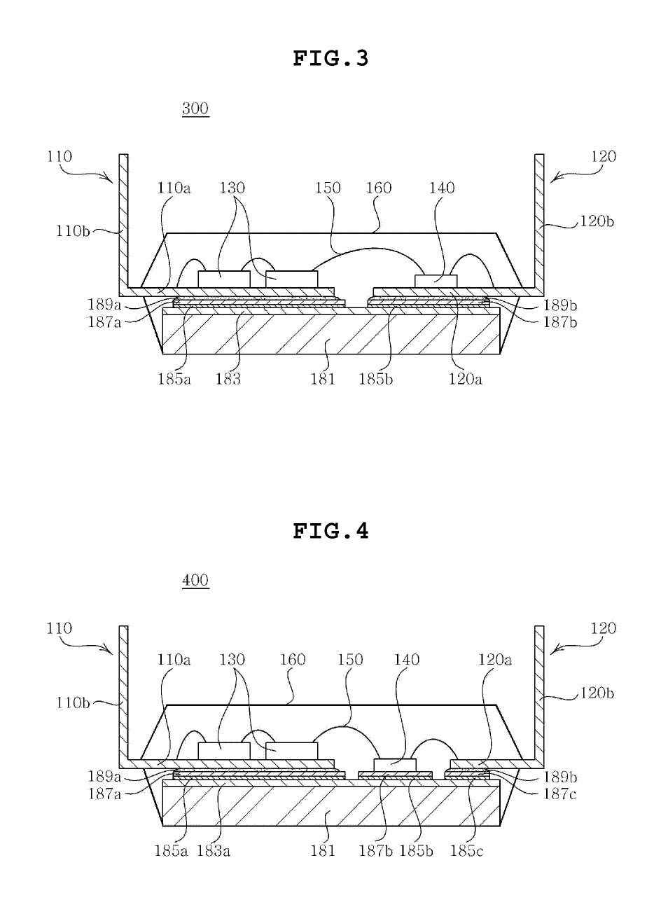

FIG. 3 is a cross-sectional view of a structure of a power module package according to a third embodiment of the present invention.

Redundant descriptions between the second embodiment and the present embodiment will be omitted here, and the same reference numerals will denote the same elements therebetween.

Referring to FIG. 3, a power module package 300 according to the present embodiment has a structure where both a second surface of one side 110a of a first lead frame 110 and a second surface of one side 120a of a second lead frame 120 are bonded onto a substrate 181.

That is, the second surface of one side 110a of the first lead frame 110 contacts a plating layer 187a of a circuit pattern, which is formed on a ceramic layer 183 formed on one surface of the substrate 181, and the other side 110b thereof externally protrudes from the substrate 181.

Likewise, the second surface of one side 120a of the second lead frame 120 contacts a plating layer 187b of a circuit pattern, which is formed on the ceramic layer 183 formed on one surface of the substrate 181, and the other side 120b thereof externally protrudes from the substrate 181.

In this case, one side 110a of the first lead frame 110 and one side 120a of the second lead frame 120 are spaced from each other while facing each other. Also, the plating layers 187a and 187b of the circuit pattern, which contact the first lead frame 110 and the second lead frame 120 respectively, are spaced apart from each other on the ceramic layer 183.

In addition, the power module package 300 according to the present embodiment may further include first semiconductor chips 130 bonded to a first surface of one side 110a of the first lead frame 110 and a semiconductor chip 140 bonded to a first surface of one side 120a of the second lead frame 120.

According to the power module package 300 of the present embodiment, a ceramic layer having excellent heat radiation property is formed on one surface of a metal substrate having excellent heat radiation property and heat conductivity, a circuit pattern with a minimum thickness is formed on the ceramic layer, and the lead frames are bonded onto the circuit pattern to allow the lead frames to function as the heat radiation substrate, thereby reducing the manufacturing cost of a heat radiation substrate and improving heat radiation property thereof.

### Fourth Embodiment

FIG. 4 is a cross-sectional view of a structure of a power module package according to a fourth embodiment of the present invention.

Redundant descriptions between the second embodiment and the present embodiment will be omitted here, and the same reference numerals will denote the same elements therebetween.

Referring to FIG. 4, a power module package 400 of the present embodiment has a structure where first semiconductor chips 130 are bonded to a first surface of one side 110a of a first lead frame 110 and a second semiconductor chip 140 is bonded onto a plating layer 187b of a circuit pattern formed on a ceramic layer 183 of the substrate 181, unlike the power module package 300 according to the above-described third embodiment.

According to the power module package 400 of the present embodiment, the second semiconductor chip 140, which is a low-power semiconductor chip generating relatively low heat, is directly bonded to the plating layer 187b of the circuit pattern formed on the substrate 181, thereby reducing the use of lead frames and hence reducing overall costs of the product.

### Fifth Embodiment

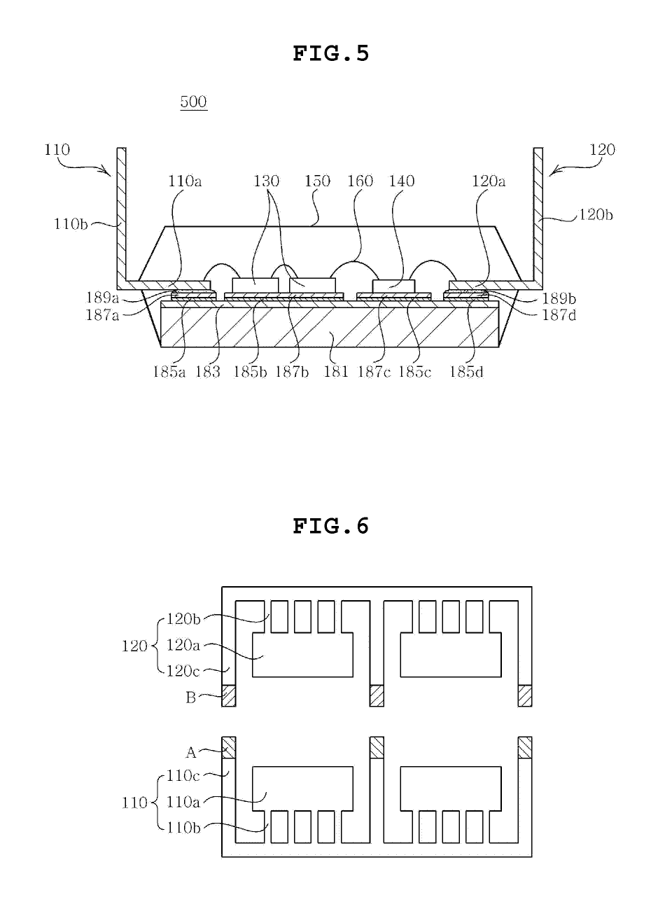

FIG. 5 is a cross-sectional view of a structure of a power module package according to a fifth embodiment of the present invention.

Redundant descriptions between the second embodiment and the present embodiment will be omitted here, and the same reference numerals will denote the same elements therebetween.

Referring to FIG. 5, a power module package 500 of the present embodiment has a structure where first semiconductor chips 130 and a second semiconductor chip 140 are all directly bonded to plating layers 187b and 187c of a circuit pattern formed on a ceramic layer 183 of a substrate 181, unlike the power module package 300 according to the above-described third embodiment.

As such, according to the power module package 500 of the present embodiment, all the first semiconductor chips 130 and the second semiconductor chip 140 are directly mounted onto the plating layers 187b and 187c of the circuit pattern formed on the substrate 181, thereby significantly reducing the use of the lead frames and reducing overall costs of the product, even while heat radiation property may be somewhat deteriorated, as compared with the power module package 300 of the third embodiment.

Method for Manufacturing Power Module Package

FIGS. 6 through 11 are process views sequentially explaining a method for manufacturing the power module package according to the first embodiment of the present invention; FIG. 12 is a plan view explaining an operation of bonding a substrate onto a lead frame in a method for manufacturing the power module package according to the second embodiment of the present invention.

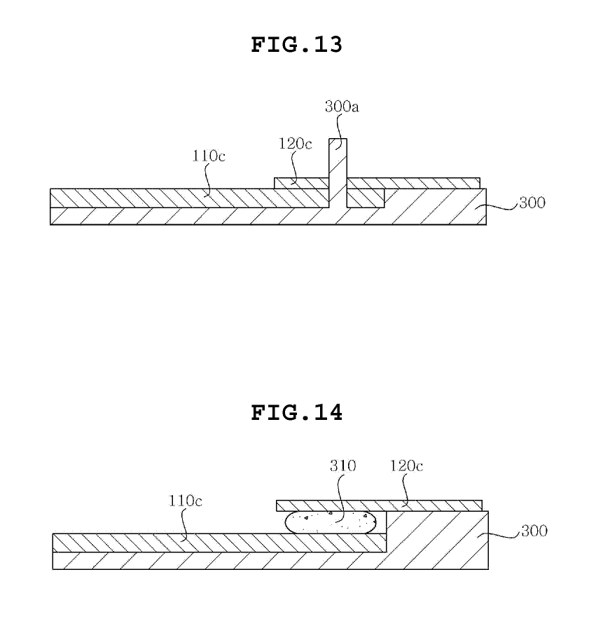

Further, FIGS. 13 and 14 are cross-sectional views explaining an operation of coupling a first lead frame and a second lead frame in a method for manufacturing the power module package according to each of the embodiments of the present invention.

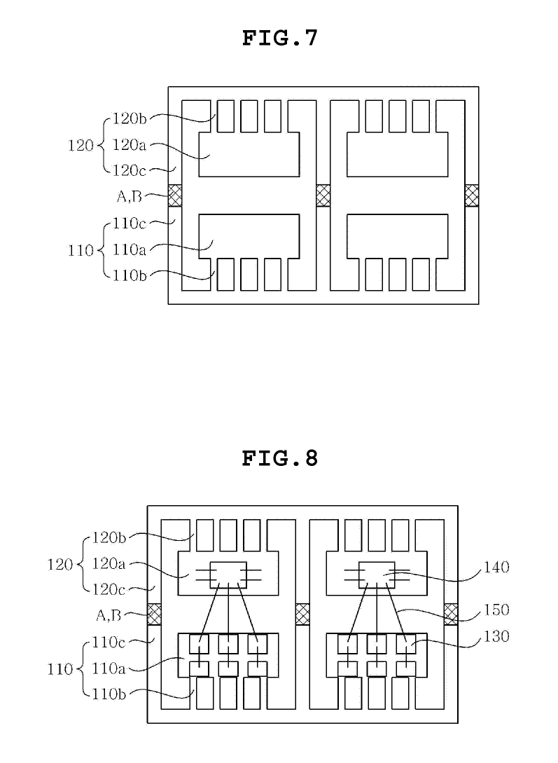

Referring to FIGS. 6 and 7, the first lead frame 110 including a first locking unit 110c and a first module unit 110a and 110b separately connected to the first locking unit 110c, the second lead frame 120 including a second locking unit 120c and a second module unit 120a and 120b separately connected to the second locking unit 120c are prepared, and the first lead frame 110 and the second lead frame 120 are coupled to each other.

In general, although the first lead frame 110 and the second lead frame 120 may be formed of copper (Cu) having good heat conductivity, the present invention is not particularly limited thereto, and the first lead frame 110 and the second lead frame 120 may be formed of any other materials having good heat conductivity.

Further, in the present embodiment, the first lead frame 110 and the second lead frame 120 may have different thicknesses. If a power device having a high heating value is bonded onto the first lead frame 110 and a control device having a low heating value is bonded onto the second lead frame 120, a thickness of the second lead frame 120 may be smaller than a thickness of the first lead frame 110, but the present invention is not particularly limited thereto.

In the present embodiment, the first locking unit 110c and the second locking unit 120c may be portions that overlap each other in order to couple the first lead frame 110 and the second lead frame 120 with each other at a subsequent process. Reference numerals 110a and 120a of the first module unit 110a and 110b and the second module unit 120a and 120b may be portions to which the first semiconductor chips 130 and the second semiconductor chip 140 are bonded at a subsequent process. However, the present invention is not particularly limited thereto. They may be merely portions to which the substrate 181 is bonded.

That is, the first locking unit 110c and the second locking unit 120c include two overlapping portions A and B, respectively, and may be coupled with each other by overlapping the two portions A and B, as shown in FIG. 7.

As described above, as a method of overlapping and fixing the first locking unit 110c and the second locking unit 120c, for example, as shown in FIG. 13, in the case where corresponding grooves (not shown) are formed in the first locking unit 110c and the second locking unit 120c, a protrusion unit 300a formed on a separate lead frame coupling member 300 may be inserted into the groove of the first locking unit 110c and the groove of the second locking unit 120c.

Alternatively, as shown in FIG. 14, the first locking unit 110c and the second locking unit 120c may overlap and be coupled with each other by a solder 310.

The methods described above are merely embodiments, and the method of coupling the first lead frame 110 and the second lead frame 120 with each other is not limited thereto.

As described above, lead frames to which different types of devices are bonded are manufactured and coupled to each other, and thus different thicknesses of lead frames are easily implemented according to capacity of devices, thereby improving efficiency, and simultaneously reducing manufacturing cost by reducing the use amount of unnecessary lead frames.

Next, as shown in FIG. 8, the first semiconductor chip 130 and the second semiconductor chip 140 are respectively bonded onto a first surface of one side 110a of the first module unit of the first lead frame 110 and a first surface of one side 120a of the second module unit of the second lead frame 120.

Although a plurality of first semiconductor chips are bonded onto the first surface of one side 110a of the first module unit of the first lead frame in FIG. 8, the present invention is not particularly limited thereto. One first semiconductor chip may also be bonded thereto.

Likewise, although one second semiconductor chip is bonded onto the first surface of one side 120a of the second module unit of the second lead frame, this is merely one embodiment, and the present invention is not particularly limited thereto. A plurality of second semiconductor chips may also be bonded thereto.

In the present embodiment, the first semiconductor chips 130 and the second semiconductor chip 140 respectively bonded onto the first surface of one side 110a of the first module unit of the first lead frame 110 and the first surface of one side 110b of the second module unit of the second lead frame 120 may be electrically connected to one side 110a of the first module unit and one side 120a of the second module unit, respectively, through wire bonding using wires 150.

In this regard, a wire bonding process may be preformed through ball bonding, wedge bonding, and stitch bonding that are well-known in the art to which the present invention pertains, but the present invention is not particularly limited thereto.

Meanwhile, according to another embodiment, before bonding the first semiconductor chips 130 and the second semiconductor chip 140 to the first surface of one side 110a of the first module unit and the first surface of one side 120a of the second module unit, respectively, the substrate 181 bonded onto the second surface of one side 110a of the first module unit may be further formed, as shown in FIG. 12.

In addition, according to still another embodiment, the substrate 181 bonded onto all the second surface of one side 110a of the first module unit and the second surface of one side 120a of the second module unit may be formed.

In the present embodiment, although the substrate 181 may be a metal substrate, the present invention is not particularly limited thereto. Examples of the substrate 181 may include a printed circuit board (PCB), an insulated metal substrate (IMS), and a pre-molded substrate.

In the present embodiment, the ceramic layer 183 may be formed on one surface of the substrate 181, i.e. one of both surfaces of the substrate 181 contacting the second surface of one side 110a of the first lead frame 110.

In this regard, the ceramic layer 183 may be formed by a spray process, a dipping process, a bar coating process, a spin coating process, etc., but the present invention is not particularly limited thereto.

In this case, since a desired thickness of ceramic may be easily formed according to the ceramic characteristics, the ceramic layer 183 of various thicknesses from 1 μm to 500 μm may be formed according to uses thereof.

Further, illumination is formed on the surface of the substrate 181 before forming the ceramic layer 183, thereby enhancing a bonding force between the ceramic layer 183 and the substrate 181.

In this regard, the illumination may be formed using a sand blast, plasma processing, wet surface processing, a brush buff, etc., but the present invention is not particularly limited thereto.

In the present embodiment, a circuit pattern may be formed on the ceramic layer 183.

In this regard, as shown in FIGS. 2 through 5, the circuit pattern may include the electroless plating layers 185a, 185b, 185c, and 185d and the electroplating layers 187a, 187b, 187c, and 187d.

Further, the circuit pattern may be a metal layer pattern including copper (Cu) or copper alloy. In this case, copper (Cu) may provide excellent electric conductivity, and a nickel (Ni) layer for preventing oxidation may be further formed on a copper circuit pattern.

Further, since the nickel (Ni) layer is not excellent in view of coating property with respect to copper (Cu) and thus may also be oxidized, a metal (Au) layer may be further formed on the nickel (Ni) layer.

However, the circuit pattern is not limited to the structure of the present embodiment, and may include metal or metal alloy having excellent electric conductivity. For example, the circuit pattern may include aluminum or aluminum alloy.

In the present embodiment, an operation of forming the circuit pattern is as follows.

First, the seed layers 185a, 185b, 185c, and 185d, which are electroless plating layers, are formed on the ceramic layer 183 formed on one surface of the substrate 181.

In this case, the seed layers 185a, 185b, 185c, and 185d may be formed by a wet plating process or a dry plating process. In this regard, the wet plating process may be an electroless plating process, the dry plating process may be a sputtering process, but the present invention is not particularly limited thereto.

In this case, the electroless plating process may be performed by using one of nickel (Ni), copper (Cu), and silver (Ag), and the sputtering process may be performed by using one of titanium (Ti), chrome (Cr), and nickel (Ni), but the present invention is not particularly limited thereto.

Next, the plating layers 187a, 187b, 187c, and 187d, which are electroplating layers, are formed on the seed layers 185a, 185b, 185c, and 185d.

In this regard, the plating layer 187a, 187b, 187c, and 187d may also be formed by using the electroplating process or the sputtering process, and may be formed of copper (Cu), but the present invention is not particularly limited thereto.

The plating layers 187a, 187b, 187c, and 187d are formed of copper (Cu) exhibiting good solder bonding property since the plating layers 187a, 187b, 187c, and 187d are bonded onto the second surface of one side 110a of the first lead frame 110, the second surface of one side 120a of the second lead frame, the first semiconductor chips 130, or the second semiconductor chip 140, by soldering, at a subsequent process.

Next, the circuit pattern may be formed, by forming an etching resist having openings for forming a circuit pattern on the plating layers 187a, 187b, 187c, and 187d, and then performing an etching process to remove portions of the plating layers 187a, 187b, 187c, and 187d and the seed layers 185a, 185b, 185c, and 185d, which are exposed by the openings for forming the circuit pattern.

Although a substractive technique is described as an example of the process of forming the circuit pattern in the present embodiment, the present invention is not limited thereto, and all processes for forming a circuit pattern generally used in a PCB field may be applied.

In the present embodiment, one side 110a of the first lead frame 110 may be bonded onto the plating layer 187a of the circuit pattern formed on the ceramic layer 183, and the other side 110b thereof may externally protrude form the substrate 181.

In this case, the bonding layer 189a may be further formed between one side 110a of the first lead frame 110 and the plating layer 187a of the circuit pattern.

In this regard, the bonding layer 189a may be a solder, and one side 110a of the first lead frame 110 and the plating layer 187a may be mechanically and electrically connected to each other by the bonding layer 189a.

As such, in the case where the first semiconductor chip is a power device having a high heating value, the substrate 181 on which the circuit pattern having high heat conductivity and the ceramic layer 183 are formed may be bonded to a surface opposite to the surface of a first lead frame, to which the first semiconductor chip is bonded, thereby remarkably improving heat radiation property.

Alternatively, according to another embodiment, as shown in FIG. 4, the first semiconductor chip 130 may be bonded to the first surface of one side 110a of the first lead frame 110, and the second semiconductor chip 140 may be bonded onto the circuit pattern of the substrate 181.

As such, the second semiconductor chip 140, which is a low-power semiconductor chip a low heating value, is directly bonded to the plating layer 187b of the circuit pattern formed on the substrate 181, thereby reducing the use of lead frames and hence reducing overall costs of the product.

In addition, according to still another embodiment, as shown in FIG. 5, all the first semiconductor chip 130 and the second semiconductor chip 140 may be bonded onto the circuit pattern of the substrate 181.

As such, all the second semiconductor chips are directly bonded to the plating layers 187b and 187d of the circuit pattern formed on the substrate 181, thereby reducing the use of lead frames and hence reducing overall costs of the product, even while heat radiation property may be somewhat deteriorated.

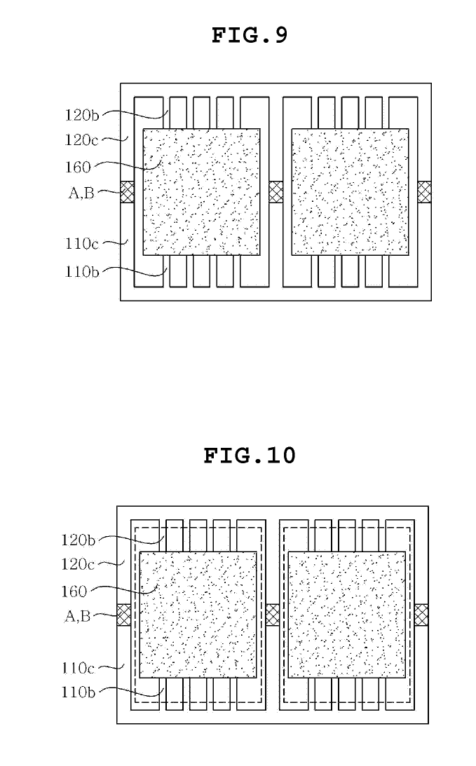

Next, referring to FIG. 9, the molding material 160 surrounding one side 110a of the first module unit, one side 120a of the second module unit, the first semiconductor chips 130, and the second semiconductor chip 140 is formed.

In this case, the molding material 160 may surround even a lower surface of the substrate 181.

The molding material 160 protects the first semiconductor chips 130 and the second semiconductor chip 140, including the wires 150, from an external environment. For example, an EMC, etc., may be used for the molding material 160, but the present invention is not particularly limited thereto.

Further, the one side 110a of the first module units and the one side 120a of the second module units may be fixed by forming the molding material 160.

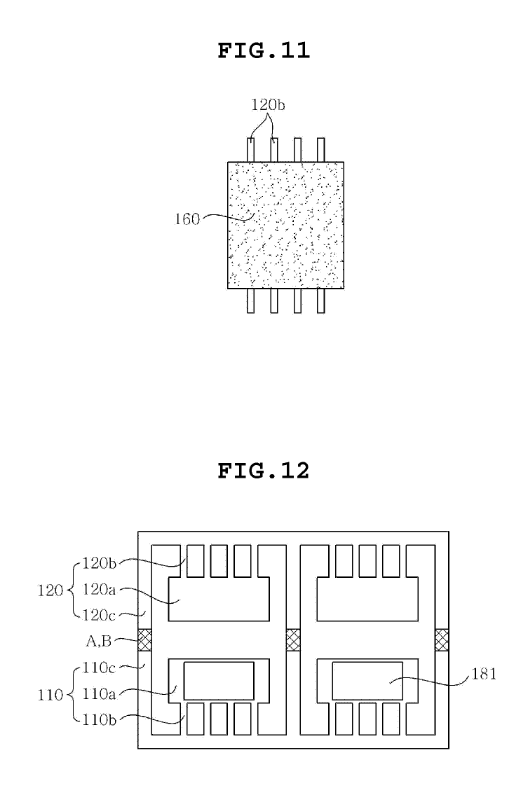

Next, referring to FIGS. 10 and 11, the first module unit 110a and 110b and the second module unit 120a and 120b are separated from the first locking unit 110c and the second locking unit 120c connected thereto, respectively, by performing a trimming process, and then the other side 110b of the first module unit and the other side 120b of the second module unit, which externally protrude from the molding material 160, are molded by performing a forming process.

According to the present invention, a thickness of a lead frame bonded onto a control device having a low heating value is smaller than a thickness of a lead frame on which a power device is mounted, thereby achieving a small-size product.

Further, as described above, a lead frame bonded onto a control device has a small thickness, and thus a fine circuit is easily formed in a control unit.

Further, a lead frame on which a power device is mounted and a lead frame on which a control device is mounted are separated from each other, thereby protecting the control device vulnerable to heat from the power device having heavy heating.

Further, lead frames are differently manufactured for each device and coupled to each other, thereby easily implementing modules having various sizes per capacity of each device.

Further, the lead frames are bonded onto a metal substrate having a ceramic layer exhibiting excellent heat radiation property and insulation property, and thus, heat generated from a heat radiation device mounted thereon can be radiated by using all the lead frames and the metal substrate, thereby improving heat radiation property.

Further, the lead frames are bonded to a metal substrate having a wiring layer formed through a plating process, and thus, a thick copper layer does not need to be used, thereby preventing delamination due to stress between metal layers.

Although the preferred embodiments of the present invention have been disclosed for illustrative purposes, they are for specifically explaining the present invention. Therefore, a power module package and a method for manufacturing the same according to the preferred embodiments of the present invention are not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims.

What is claimed is:

1. A power module package, comprising:
a first lead frame; and
a second lead frame,
wherein the first lead frame and the second lead frame are spaced apart from each other, and the first lead frame and the second lead frame have different thicknesses.

2. The power module package as set forth in claim 1, further comprising:
at least one first semiconductor chip bonded onto a first surface of one side of the first lead frame; and
at least one second semiconductor chip bonded onto a first surface of one side of the second lead frame.

3. The power module package as set forth in claim 2, wherein, in the case where the first semiconductor chip is a power device and the second semiconductor chip is a control device, the thickness of the second lead frame is smaller than the thickness of the first lead frame.

4. The power module package as set forth in claim 2, further comprising a molding material surrounding one side of the first lead frame, one side of the second lead frame, the first semiconductor chip, and the second semiconductor chip.

5. The power module package as set forth in claim 2, further comprising a substrate contacting a second surface of one side of the first lead frame,
the substrate including:
a ceramic layer formed on a surface contacting the second surface of one side of the first lead frame; and
a circuit pattern formed on the ceramic layer.

6. The power module package as set forth in claim 1, further comprising a substrate contacting both a second surface of one side of the first lead frame and a second surface of one side of the second lead frame,
the substrate including:
a ceramic layer formed on a surface contacting both the second surface of one side of the first lead frame and the second surface of one side of the second lead frame; and
at least one circuit pattern formed on the ceramic layer.

7. The power module package as set forth in claim 6, further comprising:
at least one first semiconductor chip bonded onto a first surface of one side of the first lead frame; and
at leas one second semiconductor chip bonded onto a first surface of one side of the second lead frame.

8. The power module package as set forth in claim 6, further comprising:
at least one first semiconductor chip bonded onto a first surface of one side of the first lead frame; and
at least one second semiconductor chip bonded onto the circuit pattern.

9. The power module package as set forth in claim 6, further comprising at least one first semiconductor chip and at least one second semiconductor chip boned onto the at least one circuit pattern,
wherein a circuit pattern to which the first semiconductor chip is bonded is spaced apart from a circuit pattern to which the second semiconductor chip is bonded.

10. A method for manufacturing a power module package, the method comprising:
preparing a first lead frame including a first locking unit and a first module unit separately connected to the first locking unit and a second lead frame including a second locking unit and a second module unit separately connected to the second locking unit; and
coupling the first lead frame and the second lead frame with each other by using the first locking unit and the second locking unit,
wherein the first lead frame and the second lead frame have different thicknesses.

11. The method as set forth in claim 10, wherein the first locking unit and the second locking unit have holes corresponding to each other, respectively, and wherein the coupling of the first lead frame and the second lead frame is performed by fitting a hole of the first locking unit and a hole of the second locking unit to a protrusion unit formed on a separate lead frame coupling member.

12. The method as set forth in claim 10, further comprising, after the coupling of the first lead frame and the second lead frame, bonding a first semiconductor chip and a second semiconductor chip onto a first surface of one side of the first module unit of the first lead frame and a first surface of one side of the second module unit of the second lead frame, respectively.

13. The method as set forth in claim 12, wherein in the case where the first semiconductor chip is a power device and the second semiconductor chip is a control device, the thickness of the second lead frame is smaller than the thickness of the first lead frame.

14. The method as set forth in claim 12, further comprising, after the coupling of the first semiconductor chip and the second semiconductor chip, forming a molding material surrounding one side of the first module unit, one side of the second module unit, the first semiconductor chip, and the second semiconductor chip.

15. The method as set forth in claim 14, further comprising:
after the forming of the molding material,
separating the first module unit and the second module unit, to which the first semiconductor chip and the second semiconductor chip are respectively bonded, from the first locking unit and the second locking unit, respectively, by performing a trimming process; and
molding the other side of the first module unit and the other side of the second module unit, which protrude externally from the molding material by performing a foaming process.

16. The method as set forth in claim 12, further comprising, before the bonding of the first semiconductor chip and the second semiconductor chip, forming a substrate contacting a second surface of one side of the first module unit of the first lead frame,
the substrate including:
a ceramic layer formed on a surface contacting the second surface of one side of the first lead frame; and
a circuit pattern formed on the ceramic layer.

17. The method as set forth in claim 10, further comprising, after the coupling of the first lead frame and the second lead frame, forming a substrate contacting both a second surface of one side of the first module unit of the first lead frame and a second surface of one side of the second module unit of the second lead frame,
the substrate including:
a ceramic layer formed on a surface contacting the second surface of one side of the first module unit of the first lead frame and a second surface of one side of the second module unit of the second lead frame; and
at least one circuit pattern formed on the ceramic layer.

18. The method as set forth in claim 17, further comprising, after the bonding of the substrate, bonding the first semiconductor chip and the second semiconductor chip onto the first surface of one side of the first module unit of the first lead frame and the first surface of one side of the second module unit of the second lead frame, respectively.

19. The method as set forth in claim 17, further comprising, after the bonding of the substrate, bonding the first semiconductor chip and the second semiconductor chip onto the first surface of one side of the first module unit of the first lead frame and the circuit pattern, respectively.

20. The method as set forth in claim 17, further comprising after the bonding of the substrate, bonding the first semiconductor chip and the second semiconductor chip onto the at least one circuit pattern,
wherein a circuit pattern to which the first semiconductor chip is bonded is spaced apart from a circuit pattern to which the second semiconductor chip is bonded.
